(19) United States
(12) Patent Application Publication
(10) Pub. No.: US 2008/0142685 A1
(43) Pub. Date: Jun. 19, 2008

(54) Integrated image sensor having a color-filtering microlens, and related system and method

(76) Inventor: William G. Gazeley, Corvallis, OR (US)

Correspondence Address: Kathy Manke;Avago Technologies Limited, 4380 Ziegler Road, Fort Collins, CO, 80525, US

(21) Appl. No.: 11/638,968

(22) Filed: Dec. 13, 2006

(51) Int. Cl. H01L 27/00

(52) U.S. Cl. 250/208.1

(57) ABSTRACT

An integrated image sensor includes a sensing element and a microlens disposed over the sensing element, where the microlens incorporates a first material that blocks a first wavelength of visible light. By eliminating separate color filters and incorporating the color-filtering function into a microlens, such an integrated image sensor may have a smaller foot print and a higher sensitivity, and may generate images of higher quality as compared to a known image sensor. Furthermore, such an image sensor may be usable in a wider range of applications as compared to a known image sensor.

### BACKGROUND

An electronic image-capture device, such as a digital camera, copier, or scanner, typically includes an integrated image sensor for converting visible light that emanates from an object into one or more corresponding electronic signals. From these electronic signals, the image-capture device creates and stores an electronic representation of an image of the object. A display device, such as a liquid-crystal or plasma display, may then convert the electronic representation into a viewable version of the image.

FIG. 1 is a cut-away perspective view of a region of pixel-array 10 of a conventional integrated color image sensor. The pixel-array 10 includes an array of microlenses 12, a first planarizing layer 14, an array of color filters 16, a second planarizing layer 18, an interconnect region 20, and an array of sensor elements 22. In addition to the pixel array 10, the image sensor may include other components, such as a memory, analog-to-digital converter (ADC), and processor (none shown in FIG. 1) disposed around the periphery of the pixel array.

Each microlens 12 is conventionally formed by depositing a region of a transparent material, such as glass or resin, on the layer 14 over a corresponding sensor element 22—dashed lines 24 outline the projected areas of the underlying sensing elements—and treating the substance such that the microlens has a convex upper surface. As discussed below in conjunction with FIG. 2, this formation process often leaves undesired gaps 26 between some or all of the microlenses 12, and may cause some or all of the microlenses to be misaligned with the respective underlying color filters 16.

The first planarizing layer 14 is conventionally formed from an oxide such as silicon oxide, a nitride such as silicon nitride, or another transparent material, and provides a planar surface on which to form the microlenses 12. The subsequently described transparent materials may also be an oxide, nitride, or other transparent material.

Each color filter 16 is formed by depositing over a corresponding sensor element 22 a mixture of a transparent material and a respective light-absorbing dye, pigment, or other material. After the formation of the color filters 16, the upper surfaces of the filters may be planed before the formation of the first planarizing layer 14.

The color of light that each filter 16 passes is indicated by the letter R (red light), G (green light), or B (blue light) in the corresponding microlens 12—the filters 16 are shown arranged in a Bayer pattern. For example, an R filter 16 includes a material that absorbs all wavelengths of light (e.g., green and blue wavelengths) other than the wavelengths in the red portion of the spectrum. That is, the R filter 16 ideally allows red light to pass from the corresponding microlens 12 to the corresponding sensor element 22, but blocks green and blue light. Therefore, the corresponding sensor element 22 ideally senses only the red light that passes through the corresponding microlens 12. In actuality, the R filter's cutoff between red and green light may not be sharp enough to completely block the shorter green wavelengths and to pass unattenuated wavelengths of red light. But for purposes of discussion, we need not consider the precise wavelength responses of the R, G, and B filters 16.

The second planarizing layer 18 is formed conventionally from an oxide or other transparent material, and provides a planar surface on which to form the color filters 16.

The interconnect region 20 includes one or more layers of e.g., transistors, interconnect lines, and vias (none shown) for routing signals between the sensing elements 22 and a controller (not shown in FIG. 1) of the image sensor on which the pixel array 10 is disposed.

Each sensing element 22 is formed in a bulk semiconductor substrate (not shown), and may be, e.g., a photo diode or a CMOS sensing element. Because the components (not shown) of the interconnect region 20 typically block some of the light from the corresponding microlens 12, each sensing element 22 typically has an effective aperture 28, which is the area of the sensing element upon which light from the corresponding microlens is incident. For example, each effective aperture 28 may equal an area that is approximately 50% of the total area of the corresponding sensing element 22. Furthermore, although each effective aperture 28 is shown as a respective continuous area centered within the sensing element 22, the effective aperture may be discontinuous and/or off center.

Furthermore, each sensing element 22 corresponds to a respective pixel of an image that the pixel array 10 captures. For example, the pixel array 10 may have dimensions of 2190×3650 sensing elements 22, which yield a relatively high-resolution image having approximately eight million pixels and a 3×5 aspect ratio.

FIG. 2 is a cut-away side view of the pixel array 10 of FIG. 1 and an optical train 34 for focusing onto the array light rays 36 emanating from an object (not shown). The optical train 34 has a focal point FP, and, although shown as a single lens, may include additional lenses and other components. FIG. 2 may not, however, be to actual scale.

Each microlens 12 has a focal point fp that is substantially coincident with the surface of the corresponding sensing element 22 at substantially the center of the element. Consequently, each microlens 12 has a focal length fl that is approximately equal to the height of the microlens apex above the surface of the corresponding sensing element 22, and has a substantially infinite focusing distance relative to the surface of the sensing element. The focal length and other optical properties of each microlens 12 depend on the ratio of the indices of refraction of the material (e.g., air) above the microlens and the material from which the microlens is made, as well as the index ratios at the boundaries of the layers 14, 16, 18, and 20. The height of the microlens 12 above the surface of the corresponding sensing element 22 is sometimes called the “stack” height, where the stack includes a microlens 12, the corresponding color filter 16, and the portions of the layers 14 and 18 and the region 20 beneath the microlens.

Still referring to FIG. 2, the operation of the pixel array 10 is discussed.

The rays of light 36 emanating from an object (not shown) are incident on the optical train 34, which focuses these rays through the focal point FP and onto the pixel array 10. The optical train 34 may be moveable so as to allow focus adjustment.

A respective one or more of the rays 36 are incident one each microlens 12, which redirects these incident rays through the layer 14, corresponding color filter 16, layer 18, and region 20 onto the corresponding sensing element 22.

Each color filter 16 allows only wavelengths of a respective color (i.e., R, G, or B) to pass from the corresponding microlens 12 to the corresponding sensing element 22.

The sensing element 22 generates an electronic signal having a value that is proportional to the intensity of the light that is incident on the sensing element's surface. For example, a sensing element 22 beneath an R color filter 16 generates an electronic signal having a value proportional to the intensity of the red light passing from the corresponding microlens 12, through the filter, and onto the sensing element's surface. Similarly, a sensing element 22 beneath a G color filter 16 generates a signal having a value proportional to the intensity of the green light passing from corresponding microlens 12, through the filter, and onto the sensing element's surface, and a sensing element beneath a B color filter generates a signal having a value proportional to the intensity of the blue light passing from the corresponding microlens, through the filter, and onto the sensing element's surface.

According to one technique for generating such a proportional electronic signal, each sensing element 22 is activated for a predetermined period of time.

While active, the sensing element 22 generates a current that is proportional to the intensity of the light that strikes the surface of the sensing element. Consequently, the more light that strikes the surface of the sensing element 22, the greater the current, and the less light that strikes the surface of the sensing element, the smaller the current.

A circuit (not shown in FIG. 2) integrates this current to generate a voltage that is proportional to the intensity of the incident light.

At the end of the period, an ADC (not shown in FIG. 2) converts the voltage into a digital intensity value.

Then, a processor (not shown in FIG. 2) processes the digital intensity values from all of the sensing elements 22 to generate an electronic representation of an image of the object (not shown in FIG. 2).

FIG. 3 is a cut-away side view of an outer region 37 of the pixel array 10 of FIG. 1. In the outer region 37, each color filter 16 is intentionally misaligned with its corresponding microlens 12, and each sensing element 22 is intentionally misaligned with its corresponding microlens and color filter. For example, the misalignment between the center of a microlens 12 and its corresponding sensing element 22 is MA. This misalignment helps the pixel array 10 to account for the larger angles of incidence of the light rays 36 on the microlenses 12 in the outer region 37. At these larger ray angles, the optical power of a microlens 12 may be insufficient to redirect some or all of the rays downward to a sensing element 22 that is aligned with the microlens. Therefore, shifting the color filters 16 and sensing element 22 outward from the optical train 34 (FIG. 2) relative to the microlenses 12 allows each microlens to direct more light through its corresponding color filter and onto its corresponding sensing element.

Still referring to FIG. 3, although shown as being uniform, the intentional misalignment MA is typically proportional to the stack height of the array 10 and also to the distance of the sensing element 22 from the center of the array. This is because the angle of the incident light rays 36, and thus the angle of the light rays redirected by the microlenses 12, increase with distance from the array center, and because the horizontal propagation distance of the redirected light rays increases with stack height. Therefore, the farther from the array center, the larger the misalignment MA.

And although the sensing elements 22 are each shown having a uniform area (only one dimension, width, shown in FIG. 3), the sensor area is also typically proportional to the stack height and to the distance from the center of the array 10 to accommodate the increased divergence of the redirected light from the microlenses 12. The divergence is proportional to the post-microlens propagation distance, which is proportional to the ray angle and to the stack height.

Referring to FIGS. 1-3, there are, unfortunately, problems associated with the pixel array 10.

Typically, it is desired that the pixel array 10 have a relatively high sensitivity. The sensitivity of the pixel array 10 is proportional to the amount of light, i.e., the number of incident rays 36, that each microlens 12 redirects onto the surface of the corresponding sensing element 22. The higher the sensitivity, the more suitable the pixel array 10 for low-light (e.g., night photography) and high-speed (e.g., photographing moving objects) applications.

It is also typically desired that the pixel array 10 capture an image of a relatively high quality. As discussed above, each sensing element 22 corresponds to a pixel of the captured image. And each pixel corresponds to a region of the object (not shown in FIGS. 1 and 2), the image of which the pixel array 10 captures. Consequently, for a high-quality image, each microlens 12 should direct onto the corresponding sensing element 22 only light emanating from the corresponding region of the object.

Moreover, it is typically desired that the “foot print” of the pixel array 10 be relatively small.

Unfortunately, the gaps 26 and the focal length fl of the microlenses 12 may degrade the sensitivity of the pixel array 10, and the gaps may also degrade the quality of images that the image sensor captures.

Referring to FIG. 2, the gaps 26 may degrade the sensitivity of the pixel array 10 by reducing the amount of light that is incident on a sensing element 22. For example, if a gap 26a did not exist, then a microlens 12a would redirect a ray 36a onto the underlying sensing element 22a. But because the gap 26a allows the ray 36a to propagate past the microlens 12a, the ray misses the sensing element 22a.

Furthermore, the relatively long focal lengths fl of the microlenses 12 may degrade the sensitivity of the pixel array 10 by reducing the amount of light that a microlens can direct onto the corresponding sensing element 22. It is known that the longer the focal length of a lens, the less light that the lens can gather and direct to its focal point. Consequently, the longer the focal length fl, the less light that a microlens 12 can gather and direct to its focal point fp, and thus the less light that the microlens can gather and direct onto the corresponding sensing element 22. Unfortunately, the stack height of the pixel array 10, and thus the focal lengths fl of the microlenses 12, may be as large as 5-6 microns (μm).

Moreover, the gaps 26 may degrade the quality of a captured image by allowing light corresponding to one pixel of the image to “contaminate” another pixel of the image—this contamination is sometimes called “cross talk.” For example, if the gap 26a did not exist, then a microlens 12a would redirect the ray 36a, which corresponds to a first pixel of the image, onto a corresponding sensing element 22a, which also corresponds to the first pixel. But the gap 26a allows the ray 36a to strike a sensing element 22b, which corresponds to a second pixel of the image. Consequently, the ray 36a striking the sensing element 22b may cause an erroneous decrease in the intensity of the first pixel and an erroneous increase in the intensity of the second pixel.

In addition, unintentional misalignment (or an error in the intentional misalignment MA) of a microlens 12 with the corresponding color filter 16 and/or sensing element 22 may further reduce the sensitivity of the pixel array 10 and the quality of an image captured by the pixel array.

Furthermore, the relatively large stack height of the pixel array 10 may cause the array to have a relatively large foot print because, as discussed above in conjunction with the outer region 37 of FIG. 3, the areas of the sensing elements 22 and the intentional misalignment MA of the sensing elements relative to the microlenses 12 are proportional to the stack height.

Moreover, because the distance between the optical train 34 and the array 10, and the optical properties of the train, may vary with application, the array 10 may need to be customized for each application. Specifically, as the angle of incidence for the light rays 36 changes, MA and the sensing-element area, also often change. Because given the relatively large stack height of the pixel array 10, even a small change in the incident-ray angle may require significant changes in MA and the sensing-element area.

### SUMMARY

An embodiment of an integrated pixel array includes a sensing element and a microlens disposed over the sensing element, where the microlens incorporates a first material that blocks a first wavelength of visible light.

By combining a microlens and a color filter into a single unit, such a pixel array may have a smaller foot print and higher sensitivity, and may generate images of higher quality, as compared to prior pixel arrays. Furthermore, such a pixel array may be usable in a wider range of applications as compared to prior pixel arrays.

### BRIEF DESCRIPTION OF THE DRAWINGS

FIG. 1 is a cut-away perspective view of a conventional integrated pixel array.

FIG. 2 is a cut-away side view of the pixel array of FIG. 1.

FIG. 3 is a cut-away side view of an outer region of the pixel array of FIG. 1.

FIG. 4 is a cut-away side view of a pixel array according to an embodiment of the invention.

FIG. 5 is a cut-away side view of the pixel array of FIG. 4 at an intermediate point of formation according to an embodiment of the invention.

FIG. 6 is a cut-away side view of the pixel array of FIG. 4 at an intermediate point of formation according to another embodiment of the invention.

FIG. 7 is a cut-away side view of an outer region of the pixel array of FIG. 4 according to an embodiment of the invention.

FIG. 8 is a cut-away side view of an integrated circuit (IC) that includes an integrated image sensor having the pixel array of FIG. 4 according to an embodiment of the invention.

FIG. 9 is a block diagram of an electronic image-capture system that incorporates the IC of FIG. 8 according to an embodiment of the invention.

### DETAILED DESCRIPTION

The following discussion is presented to enable a person skilled in the art to make and use one or more embodiments of the invention. The general principles described herein may be applied to embodiments and applications other than those detailed below without departing from the spirit and scope of the invention. Therefore the present invention is not intended to be limited to the embodiments shown, but is to be accorded the widest scope consistent with the principles and features disclosed or suggested herein.

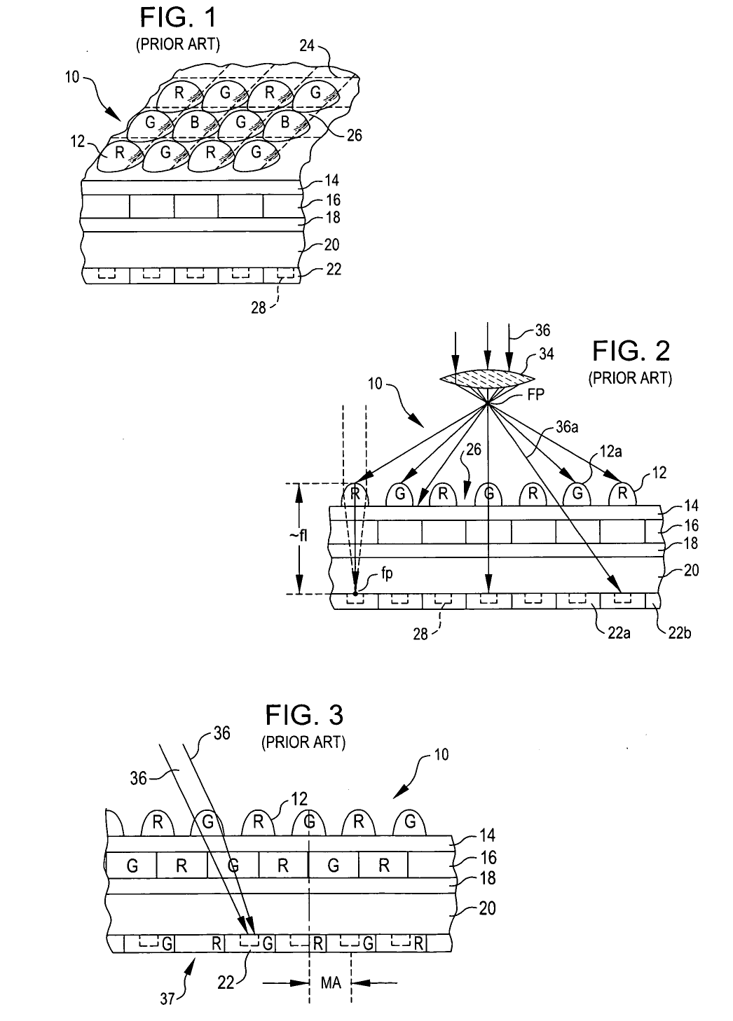

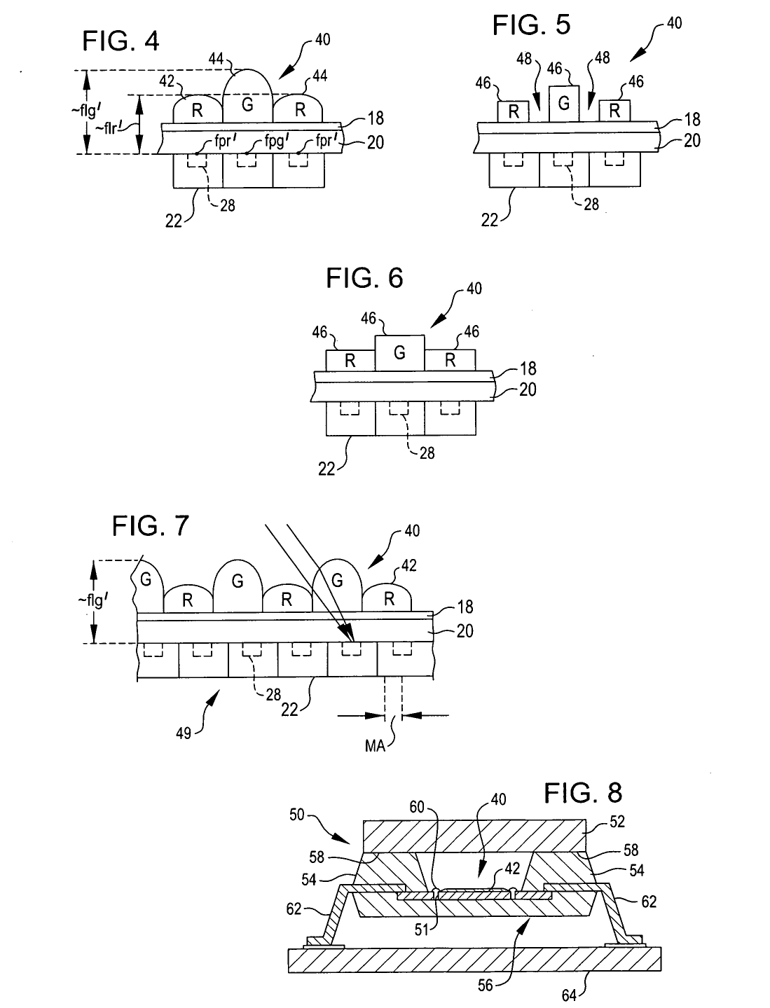

FIG. 4 is a cut-away side view of an inner region of a pixel array 40 according to an embodiment of the invention. As discussed below, the pixel array 40 may have a greater sensitivity and generate images of a higher quality as compared to prior pixel arrays such as the pixel array 10 of FIG. 1. Furthermore, like numbers are used in FIG. 4 to reference structures common to FIGS. 1-4.

Referring to FIG. 4, the pixel array 40 includes color-filtering microlenses 42, each of which is effectively a combination of a microlens 12 and a corresponding color filter 16 of FIGS. 1-3.

Each microlens 42 is formed from a mixture of a transparent material, such as glass or resin, and a light-absorbing material, such as a dye, and has a convex upper surface 44.

The light-absorbing material allows only a predetermined color (i.e., one or more predetermined wavelength(s)) of light to pass through the microlens 42 to the underlying sensing element 22. For example, the light-absorbing material in an R microlens 42 allows only red light to pass through the R microlens to the sensing element 22. Similarly, the light-absorbing material in a G microlens 42 allows only green light to pass through the G microlens to the underlying sensing element 22, and the light-absorbing material in a B microlens 42 allows only blue light to pass through the B microlens to the underlying sensing element. Because such light-absorbing materials are known, a more detailed description of these materials is omitted.

Furthermore, the R, G, and B microlenses 42 have different heights, and the convex surface 44 provides each microlens 42 with a respective focal length fl′ approximately equal to the microlens' height. Because the transparent material from which the microlenses 42 are formed causes different wavelengths of incident light to refract at different angles, the heights of the R, G, and B microlenses are different so as to “tune” the optical properties (e.g., the focal points) of the microlenses to the respective wavelengths they pass. For example, assume that the convex surfaces 44 of an R microlens 42 and a G microlens have substantially the same shape—this may occur in practice, because depending on the process used to form the microlenses, it may be difficult to form the convex surfaces 44 having different predetermined shapes. Consequently, the different angles at which the respective convex surfaces 44 refract red and green light may cause the focal length flr′ of the R microlens 42 for passed red light to be different from the focal length flg′ of the G microlenses for passed green light. But by forming the R and G microlenses 42 to have respective heights approximately equal to flr′ and flg′, one can set the corresponding focal points fpr′ and fpg′ substantially at the surfaces of the respective sensing elements 22 as may be desired. For similar reasons, the heights of the B microlenses 42 (not shown in FIG. 4) may be different than the heights of the R and G microlenses. Furthermore, although the G microlenses 42 are shown as being taller than the R microlenses, the G microlenses may be shorter than the R microlenses. In addition, the heights of the R, G, and B microlenses 42 may together be constrained within a predetermined range having a predetermined tolerance to provide predictability to the height of the image sensor that incorporates the pixel array 40.

Still referring to FIG. 4, the microlenses 42 may increase the sensitivity of the pixel array 40 and the quality of the images captured by the pixel array as compared to prior pixel arrays such as the pixel array 10 of FIG. 1.

Because each microlens 42 is effectively a combination of a microlens 12 and color filter 16 (FIGS. 1-3), the stack heights (i.e., the respective heights of the R, G, and B microlenses 42 above the sensing elements 22) of the pixel array 40 may be less than the stack height of the pixel array 10 (FIG. 1). For example, the stack heights of the pixel array 40 may range from approximately 4.5-5.5 μm or shorter. These reduced stack heights may allow the focal lengths fl′ of the microlenses 42 to be shorter than the focal length fl of the microlenses 12, and thus may increase the amount of light that each microlens 42 can gather and direct onto an underlying sensing element 22 as compared to the amount of light that a microlens 12 can gather and direct. Consequently, the increased light-gathering and light-directing capacities of the microlenses 42 may increase the sensitivity of the pixel array 40 relative to prior pixel arrays. Furthermore, the pixel array 40 may be said to have a “stack height” that is equal to the stack height of the tallest microlenses 42. So in this embodiment the “stack height” of the pixel array 40 is equal to the stack height of the green microlenses 42.

Furthermore, the lack of gaps between the microlenses 42 may reduce the number of light rays that “miss” the appropriate sensing element 22, and thus may reduce the occurrence of pixel “cross talk;” consequently, the lack of gaps may improve the sensitivity of and the image quality provided by the pixel array 40 as compared to prior pixel arrays.

In addition, because the microlenses 42 include color-filtering materials, the color filters and microlenses of the pixel array 40 are effectively self-aligned. This effective self-alignment may also increase the sensitivity of and the image-quality provided by the pixel array 40 as compared to prior pixel arrays.

The reduced stack heights of the microlenses 42 over the sensing elements 22 and the lack of gaps may also provide the pixel array 40 with other advantages over prior pixel arrays. For example, the omission of the layer 14 and the separate color filters 16 of FIGS. 1-3 may reduce the cost of manufacturing an image sensor that incorporates the pixel array 40 as compared to cost of an image sensor that incorporates the pixel array 10 of FIGS. 1-2.

Still referring to FIG. 4, when installed in an image-capture system (not shown in FIG. 4) such as a digital camera, the pixel array 40 operates similarly to the pixel array 10 of FIG. 1, but potentially with a higher sensitivity and providing a better image quality as discussed above.

FIG. 5 is a cut-away side view of the portion of the pixel array 40 of FIG. 4 at an intermediate stage of formation according to an embodiment of the invention.

Referring to FIGS. 4 and 5, the process for forming the pixel array 40 is discussed according to an embodiment of the invention.

Referring to FIG. 5, the sensing elements 22 are formed in a known manner, and the interconnect region 20 is formed over the sensing elements in a known manner.

Next, the planarizing layer 18 is formed over the interconnect region 20 in a known manner.

Then, an R segment 46 formed from a mixture of a transparent material and a material that passes red light and absorbs green and blue light is deposited on the layer 18 in each R-pixel location. A mask (not shown in FIG. 4) is used to prevent formation of the R segments 46 on the G-pixel and B-pixel locations (B-pixel locations not shown in FIGS. 4-5). Similarly, a G segment 46 formed from a mixture of the transparent material and a material that passes green light and absorbs red and blue light is deposited on the layer 18 in each G-pixel location, and a B segment 46 (not shown in FIG. 5) formed from a mixture of the transparent material and a material that passes blue light and absorbs red and green light is deposited on the layer 18 in each B-pixel location. The R, G, and B segments 46 are formed such that gaps 48 are present between the segments. For example, the gaps may be approximately 0.25 μm wide. Furthermore, the mixtures used to form the R, G, and B segments 46 are premixed in a known manner before being deposited on the layer 18.

Referring to FIGS. 4 and 5, the R, G, and B segments 46 (B segments not shown in FIG. 5) are then heated to form the R, G, and B microlenses 42 (B microlenses not shown in FIG. 4). This heating is often called “reflow.” When heated, the R, G, and B segments 46 soften and expand outward and against each other such that there are few if any gaps 48 remaining between the formed microlenses 42. Furthermore, surface tension in the softened segments 46 causes the upper surfaces of the segments to “bead” like water on a waxed car hood, thus forming the convex upper surfaces 44 of the microlenses 42. Where the R, G, and B segments 46 have substantially the same lateral dimensions (i.e., dimensions in the plane of the layer 18) and are made from the same transparent material, then the surface tension typically causes the convex upper surfaces 44 to have a substantially uniform shape.

Next, the remaining portions (not shown in FIGS. 4-5) of the integrated image sensor that includes the pixel array 40 are formed in a conventional manner. Alternatively, some or all of these remaining portions may be formed contemporaneously with the pixel array 40.

Still referring to FIGS. 4-5, alternate embodiments of the pixel sensor 40 are contemplated. For example, the microlenses 42 may have substantially equal heights, but may have differently shaped convex surfaces 44 so that all of the R, G, and B microlenses 42 have substantially the same heights (i.e., flr′=flg′=flb′˜the height of the microlenses where flb′ is the focal length of the B microlenses, which are not shown in FIG. 4). One technique for achieving the differently shaped convex surfaces 44 is forming the R, G, and B segments 46 from respective transparent materials that have different reflow properties. Or, the R, G, and B microlenses 42 may have both different heights and differently shaped convex surfaces 44. Alternatively, the R, G, and B microlenses 42 may be formed from different transparent materials having different indices of refraction to further “tune” the focal lengths fl′ of the microlenses. Furthermore, the R, G, and B microlenses 42 may have different lateral dimensions. In addition, not all of the R microlenses 42 may have the same dimensions and properties. For example, some R microlenses 42 may be taller than other R microlenses, or may have more or less of the blue-green-light-absorbing material than other R microlenses. Similar alternatives are contemplated for the G and B microlenses 42. Moreover, the layer 18 may be omitted, and the microlenses 42 may be disposed directly on the interconnecting region 20. Furthermore, the microlenses 42 may pass colors of light different than red, green, and blue to conform to a color space other than RGB, such as CMY (cyan, magenta, yellow). In addition, one may grow the R, G, and B segments 46 on the layer 18 instead of depositing them on the layer. Alternatively, one may form an array of the microlenses 42 separately (e.g., by injection molding) and then place the array on the layer 18 (or directly on the interconnection region 20) in alignment with the sensing elements 22. Moreover, one may include an infrared(IR)-absorbing material in the microlenses 42 to eliminate the need for a separate infrared filter. Techniques for separately forming a microlens array and for including an IR-absorbing material in the microlenses 42 are described in commonly assigned U.S. patent application Ser. No. 10/926,152, which is incorporated by reference. Furthermore, instead of being formed in a bulk semiconductor substrate, the sensing elements 22 may be formed from semiconductor thin films or polymers on a glass or ceramic substrate, or may be formed in another manner.

FIG. 6 is a cut-away side view of a portion of the pixel array 40 of FIG. 3 at an intermediate stage of formation according to another embodiment of the invention. Referring to FIG. 6, the process for forming the pixel array 40 according to this embodiment of the invention is similar to the process described above in conjunction with FIGS. 4 and 5, except that the R, G, and B segments 46 (the B segments are not shown in FIG. 6) are deposited onto the layer 18 in contact with one another. As compared to a process that deposits the segments 46 with gaps 48 therebetween as described above in conjunction with FIG. 5, depositing contiguous segments may further reduce or eliminate the occurrence of gaps between the microlenses 42, and may reduce the widths of these gaps if they occur. Alternate embodiments of this contiguous-segment process are contemplated, including alternate embodiments that are similar to those described above in conjunction with FIGS. 4 and 5 for the non-contiguous-segment process.

FIG. 7 is a cut-away side view of an outer region 49 of the pixel array 40 of FIG. 4 according to an embodiment of the invention.

In the outer region 49, each sensing element 22 is intentionally misaligned with its corresponding color-filtering microlens 42 to help the pixel array 40 account for the larger angles of incidence of the light rays 36 on the microlens as discussed above in conjunction with FIG. 3.

But the reduced stack height (˜flg′) of the pixel array 40 as compared to the known pixel array 10 of FIGS. 1-3 may allow a reduction in the foot print of the pixel array 40 for a given number of sensing elements 22 as compared to the known pixel array. Because the intentional misalignment MA and the area of a sensing element 22 are proportional to the stack height, the reduced stack height of the pixel array 40 may allow a reduction in both the intentional misalignment MA and the areas of the sensing elements 22. And because the foot print of the pixel array 40 is proportional to MA and to the areas of the sensing elements 22, a reduction in these quantities reduces the array foot print for a given number of sensing elements.

Moreover, the reduced stack height reduces the dependency of MA and the sensing-element area on the incident angle of the rays 36, and thus may render the pixel array 40 suitable for use in applications having a wider range of incident-ray angles as compared to the pixel array 10 of FIGS. 1-3. This may reduce costs, as fewer versions of the array 40 may be produced for a given range of incident-ray angles as compared to the number of versions needed for the known pixel array 10.

Still referring to FIG. 7, although the sensing elements 22 are shown having a uniform area, and the microlenses 12 and sensing elements are shown having a uniform intentional misalignment MA, the sensing-element areas and the misalignment MA may increase as one moves further away from the center of the pixel array 40. That is, the sensing-element area and the misalignment MA may be proportional to the distance of the sensing element 22 from the center of the array 40.

Furthermore, the microlenses 42 in the outer region 49 may be formed as described above in conjunction with FIGS. 5-6.

FIG. 8 is a cut-away side view of an integrated circuit (IC) 50 that includes an image-sensor die 51, which incorporates the pixel array 40 of FIG. 4 according to an embodiment of the invention. The IC 50 includes a glass plate 52 or other transparent cover attached to a side wall 54 of a shell-case sensor package 56, which surrounds the die 51. The package side wall 54 is of a suitably durable material, such as plastic or ceramic, sized to provide separation between the lower face of the plate 52 and the upper convex surfaces of the microlenses 42. The plate 52 is bonded to upper extents 58 of the wall 54 by a sealant adhesive and protects the microlenses 42. Bond wires 60 connect pads (not shown in FIG. 8) of the die 51 to package leads 62, which are bonded to the pads (not shown in FIG. 8) on a circuit board 64 and electrically connect the die 51 to external circuitry (not shown in FIG. 8). An optical train (not shown in FIG. 8), such as the focusing-lens assembly 34 of FIG. 2, when used, is mounted by a suitable supporting structure (not shown in FIG. 8) to the board 64 so as to be in optical-path alignment with the microlenses 42.

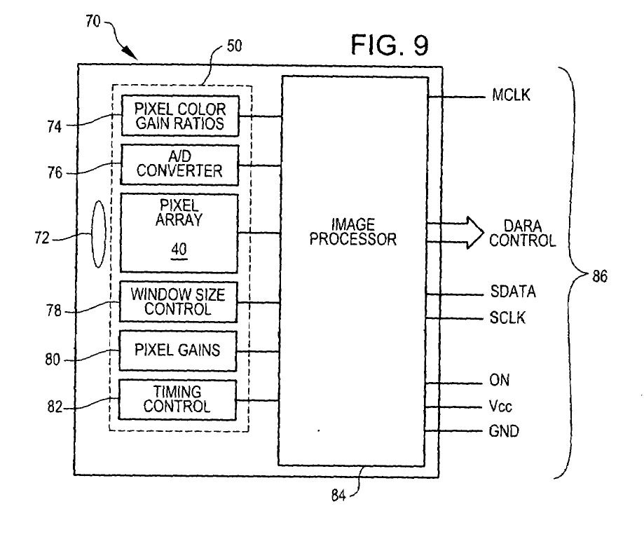

FIG. 9 is a block diagram of an electronic image-capture system 70 that incorporates the image-sensor IC 50 of FIG. 8 according to an embodiment of the invention. In addition to the pixel array 40, which receives light emanating from an object (not shown in FIG. 9) through a field lens 72, the image-sensor IC 50 also includes the following circuitry: a pixel color-gain ratio controller 74, A/D converter 76, window-size controller 78, pixel-gain controller 80, and timing controller 82. These circuits may be integrated onto the same die 51 (FIG. 8) as the pixel array 40, or may be disposed on one or more different dies. An image processor 84 having known circuitry and operation is connected to the sensor IC 50 and has the various control and data lines 86 for controlling the circuitry on the IC 50, for receiving electronic pixel information from the pixel array 40, and for processing the pixel information to form an image of the object. Because such circuitry and signal processing are known, they are not described further. Furthermore, although shown as being separate from the IC 50, part or all of the processor 84 may be disposed on the IC, and may be integrated onto the same die 51 that includes the pixel array 40, or may be integrated onto a different die.

From the foregoing it will be appreciated that, although specific embodiments have been described herein for purposes of illustration, various modifications may be made without deviating from the spirit and scope of the invention. Furthermore, where an alternative is disclosed for a particular embodiment, this alternative may also apply to other embodiments even if not specifically stated.

What is claimed is:

1. An integrated image sensor, comprising:
a first sensing element operable to sense light; and
a first microlens disposed over the sensing element and including a first material that blocks a first wavelength of visible light.

2. The integrated image sensor of claim 1 wherein the first material absorbs the first wavelength of visible light.

3. The integrated image sensor of claim 1 wherein the first material blocks a second wavelength of visible light.

4. The integrated image sensor of claim 1 wherein:
the first wavelength of visible light comprises green light; and
the first material also blocks blue light and passes red light.

5. The integrated image sensor of claim 1 wherein:
the first wavelength of visible light comprises red light; and
the first material also blocks blue light and passes green light.

6. The integrated image sensor of claim 1 wherein:
the first wavelength of visible light comprises green light; and
the first material also blocks red light and passes blue light.

7. The integrated image sensor of claim 1 wherein the first microlens includes:
a surface having a curved portion; and
a focal length approximately equal to a height between the curved surface portion and the sensing element.

8. The integrated image sensor of claim 1 wherein the first microlens includes:
a surface having a curved portion; and
a focal length approximately equal to a height between an apex of the curved surface portion and the sensing element.

9. The integrated image sensor of claim 1 wherein the first microlens includes:
a surface having a curved portion; and
a height between an apex of the curved surface portion and the sensing element being less than five microns.

10. The integrated image sensor of claim 1, further comprising:
wherein the first material is transparent to a second wavelength of visible light;
a second sensing element operable to sense light; and
a second microlens disposed over the second sensing element and including a second material that blocks the second wavelength of visible light and that is transparent to the first wavelength of visible light.

11. The integrated image sensor of claim 1, further comprising:
a second sensing element operable to sense light; and
a second microlens disposed over the second sensing element and contiguous with the first microlens.

12. The integrated image sensor of claim 1, further comprising:
wherein the first microlens includes a surface having a curved portion;
a second sensing element operable to sense light;
a second microlens disposed over the second sensing element and including a surface having a curved portion; and
wherein a first height between the curved surface portion of the first microlens and the first sensing element is different than a second height between the curved surface portion of the second microlens and the second sensing element.

13. The integrated image sensor of claim 1 wherein the microlens includes a second material that blocks infrared light.

14. The integrated image sensor of claim 1, further comprising:
an array of sensing elements each operable to sense light, the array including the first sensing element; and
an array of microlenses disposed over the array of sensing elements, each microlens including a material that blocks a respective wavelength of visible light, the array including the first microlens.

15. An integrated image sensor, comprising:
an array of sensing elements operable to sense light;
an interconnect region disposed over the array;
a microlens array disposed over the interconnect region; and
no more than two layers between the interconnect region and the microlens.

16. The integrated image sensor of claim 15, further comprising no more than one layer between the interconnect region and the microlens.

17. A system for electronically capturing an image of an object, the system comprising:
an integrated image sensor, comprising,
a first sensing element operable to sense light emanating from the object, and
a first microlens disposed over the sensing element and including a first material that blocks a first wavelength of visible light.

18. A system for electronically capturing an image of an object, the system comprising:
an integrated image sensor, comprising,
an array of sensing elements operable to sense light emanating from the object,
an interconnect region disposed over the array,
a microlens array disposed over the interconnect region, and
no more than two layers between the interconnect region and the microlens.

19. A method, comprising:
forming a first segment over a first light-sensing element having a dimension, the segment operable to block a first wavelength of visible light; and
shaping the segment into a first lens having substantially the same dimension as the light-sensing element.

20. The method of claim 19 wherein forming the segment comprises depositing the segment over the light-sensing element.

21. The method of claim 19 wherein the segment comprises a mixture of a transparent first material and a second material that absorbs the first wavelength.

22. The method of claim 19 wherein shaping the segment comprises softening the segment.

23. The method of claim 19, further comprising:
forming a substantially planar layer over the light-sensing element; and
forming the segment over the layer.

24. The method of claim 19, further comprising:
forming a second segment over a second light-sensing element having substantially the dimension and adjacent to the first light-sensing element, the second segment operable to block a second wavelength of visible light and being separated from the first segment by a gap; and
shaping the first and second segments into the first lens and a second lens, respectively, by causing the first and second segments to flow into and close the gap, the second lens having substantially the same dimension as the second light-sensing element.

25. The method of claim 19, further comprising:
forming a second segment over a second light-sensing element having substantially the dimension and adjacent to the first light-sensing element, the second segment operable to block a second wavelength of visible light and being contiguous with the first segment; and
shaping the first and second segments into the first lens and a second lens, respectively, by softening the first and second segments, the second lens having substantially the same dimension as the second light-sensing element.
